(19) United States
(12) Patent Application Publication
(10) Pub. No.: US 2026/0053067 A1
(43) Pub. Date: Feb. 19, 2026

(54) CHIPLET CARTRIDGE

(71) Applicant: VueReal Inc., Waterloo (CA)

(72) Inventor: Gholamreza CHAJI, Kitchener (CA)

(73) Assignee: VueReal Inc., Waterloo, ON (CA)

(21) Appl. No.: 19/119,006

(22) PCT Filed: Oct. 10, 2023
(86) PCT No.: PCT/CA2023/051337

§ 371 Date: Apr. 7, 2025

Related U.S. Application Data
(60) Provisional application No. 63/414,010, filed on Oct. 7, 2022.

(51) Int. Cl. H01L 25/16; H01L 25/075; H10H 20/857; H10H 29/03; H10H 29/24; H10H 29/85

(52) U.S. Cl. CPC H01L 25/167; H01L 25/0753; H10H 20/857; H10H 29/03; H10H 29/24; H10H 29/8508

(57) ABSTRACT

The present invention discloses cartridge structure and chiplets and cartridge layers. The invention further discloses, method of transferring pixel elements with chiplet cartridge structure and also various methods of fabrication for pixel elements having chiplet cartridge.

### BACKGROUND AND FIELD OF THE INVENTION

The present invention relates to cartridge structure, pixel elements and their fabrication and transfer processes.

### SUMMARY

The present invention relates to a cartridge structure where the structure comprising, a substrate, cartridge layers and a pixel element, the pixel element comprising microdevices, the microdevice having at least one first set of contact pad facing a chiplet, the chiplet with pixel driving circuits having at least one first set of chiplet pad coupled to first set of contact pad of the microdevice, and the chiplet having a second set of chiplet pad on an opposite side from the first chiplet pad.

The present invention also rates to a method to transfer a chiplet cartridge, the method comprising, having the chiplet cartridge wherein the chiplet cartridge comprising: a substrate, cartridge layers and a pixel element, with the pixel element comprising microdevices, the microdevice having at least one first set of contact pad facing a chiplet, the chiplet with pixel driving circuits having at least one first set of chiplet pad coupled to first set of contact pad of the microdevice, the chiplet having a second set of chiplet pad on an opposite side from the first chiplet pad; the method further comprising, having the second set of pads bonded to a system substrate and coupled to electrodes on the system substrate, and having the cartridge layer release a bonded pixel element to remain in the system substrate.

The present invention also relates to a method to fabricate pixel elements comprising chiplet cartridge, the method comprising, fabricating a micro chiplet, forming pads on a surface of the micro chiplet, bonding microdevices the micro chiplet, forming interconnections, optical layers, color conversion layers, thinning a backside of the micro chiplet is thinned, forming a VIA to connect micro chiplet interface signals to another side of the micro chiplets, forming pads on a second side of the micro chiplet and a structure from the microdevice side is bonded to a cartridge layer.

The present invention further relates to a cartridge structure the structure comprising, a substrate, cartridge layers and a pixel element, the pixel element comprising chiplets connected to the cartridge layers, a chiplet having a first set of chiplet pads facing away from substrate and a second set of chiplet pads facing substrate, microdevices coupled to the chiplet through at least one of the first set of chiplet pads, and the microdevice having at least one first set of microdevice pads facing the chiplet.

The present invention also relates to a method to transfer a chiplet cartridge, the method comprising, having the chiplet cartridge wherein the chiplet cartridge comprising: a substrate, cartridge layers and a pixel element, the pixel element comprising chiplets connected to the cartridge layers, a chiplet having a first set of chiplet pads facing away from substrate and a second set of chiplet pads facing substrate, microdevices coupled to the chiplet through at least one of the first set of chiplet pads, and the microdevice having at least one first set of microdevice pads facing the chiplet, the method further comprising, having the second set of pads bonded to a system substrate and coupled to electrodes on the system substrate, and having the cartridge layer release a bonded pixel element to remain in the system substrate.

The present invention also relates to a method to fabricate pixel elements comprising a chiplet cartridge, the method comprising, fabricating a micro chiplet, forming pads on a surface of the micro chiplet wherein the micro chiplet has a first set of chiplet pads facing away from a substrate and a second set of chiplet pads facing the substrate, bonding microdevices the micro chiplet wherein the microdevices coupled to the chiplet through at least one of the first set of chiplet pads, forming interconnections, optical layers, color conversion layers, thinning a backside of the micro chiplet, forming a VIA to connect micro chiplet interface signals to another side of the micro chiplets, forming pads on a second side of the micro chiplet, and a structure from the microdevice side is bonded to a cartridge layer.

### BRIEF DESCRIPTION OF DRAWINGS

The foregoing and other advantages of the disclosure will become apparent upon reading the following detailed description and upon reference to the drawings.

FIG. 1A and FIG. 1B shows the cartridge comprising pixel elements and cartridge layers.

FIG. 2A and FIG. 2B shows another cartridge structure comprising pixel elements and cartridge layers.

### DETAILED DESCRIPTION

The following description relates to structure and method of fabrication for a chiplet cartridge. It also details aspects of the transfer mechanism and method of the chiplet cartridge.

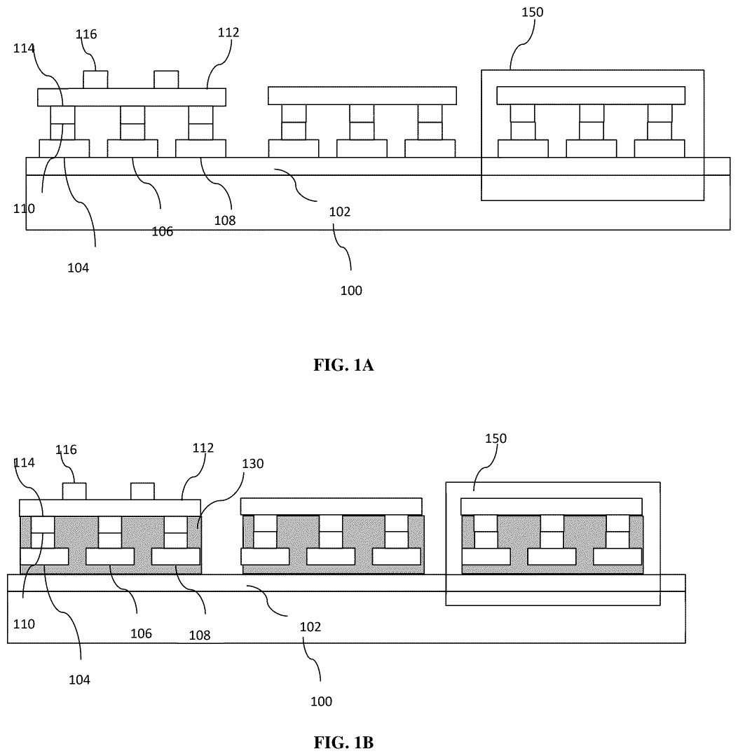

FIG. 1A shows a cartridge structure that includes substrate 100, cartridge layers 102, and pixel element 150. The pixel element 150 can include microdevices 104, 106, and 108. Microdevices 104, 106, and 108 can be the same or different types of devices. The microdevice can have at least one first set of contact pad 110 facing away from the substrate 100. A chiplet 112 with pixel driving circuits has at least one first set of chiplet pad 114 coupled to pad 110 of the microdevice. The chiplet can have a second set of chiplet pad 116 on the opposite side from the first chiplet pad 114. The chiplet can be coupled to more than one microdevice 104, 106, and 108. There can be a separate bonding material holding the chiplet and microdevice together. The first set of microdevice pads 110 and the chiplet pads 114 can be bonded together and hold the microdevices and the chiplet together. Here the microdevices can be microLEDs.

Chiplet 112 can include a substrate. Either the first set of pad 114 or the second set of pad 116 is coupled to the pixel circuit through VIAs in the chiplet substrate.

During the transfer mechanism, the second set of pads can be bonded to a system substrate and coupled to electrodes on the system substrate. The electrodes can provide power, control signals, data or another form of electrical voltage or current. The cartridge layer 102 releases the bonded pixel element 150 to remain in the system substrate.

In one embodiment, the microdevices 104, 106, and 108 can have pads on the side of the devices that are different from the first set of microdevice pads. After transferring pixel elements 150 to the system substrate, the electrode can be formed to couple the second set of microdevices pads to an electrode or contact in the system substrate.

In one method of developing pixel elements related to FIG. 1A, the micro chiplet is fabricated using circuit technologies such as CMOS or other technologies. The pads 114 are formed on the surface of the micro chiplet 112. The microdevices 104, 106, 108 are bonded to the micro chiplet 112. Here, other processes may have been done such as forming interconnections, optical layers, color conversion layers or other device types. After such a process, the backside of the micro chiplet is thinned or the wafer is removed. Here, VIA is formed to connect micro chiplet interface signals to the other side of the micro chiplets. Pads 116 can form on the second side of the micro chiplet. The structure from the microdevice side is bonded to a cartridge substrate or the cartridge layers are formed on the surface of structure that include microdevices. The process of VIA formation and interconnection to the chiplet signals can be done prior to microdevice integration.

In another related method of developing pixel elements, the microdevices are integrated into a cartridge substrate. Then the micro chiplet is bonded to the microdevices.

FIG. 1B shows a related embodiment where the first surface of the micro chiplet including the microdevices are covered by a passivation layer 130. In one related embodiment, the passivation layer 130 is bonded to the cartridge layers.

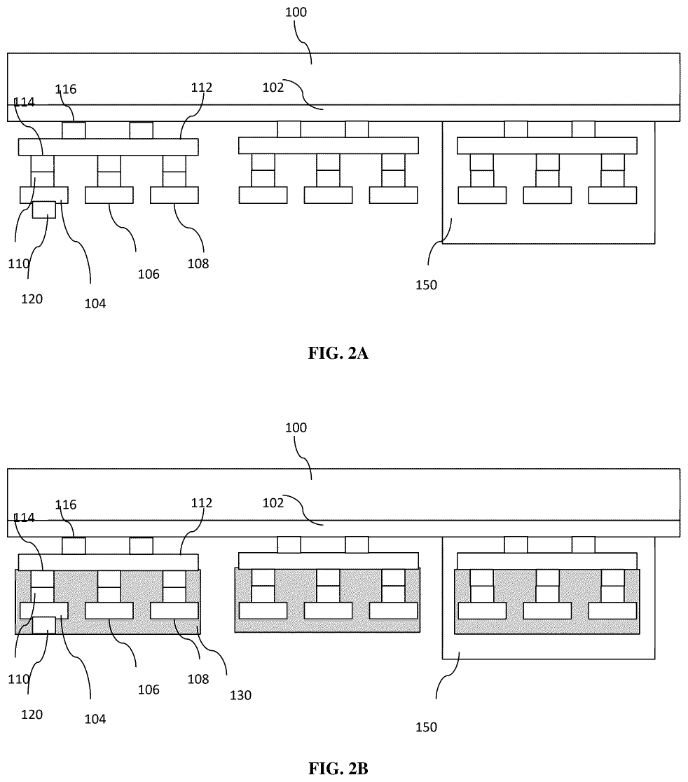

FIG. 2A shows a cartridge structure that includes substrate 100, cartridge layers 102, and pixel element 150. The pixel element 150 can include chiplets 114 connected to the cartridge layers 102. Chiplet 112 can have the first set of chiplet pads facing away from substrate 100 and the second set of chiplet pads facing substrate 100. Microdevices 104, 106, and 108 are coupled to the chiplet through at least one of the first chiplet pads. Microdevices 104, 106, and 108 can be the same or different types of devices. The microdevice can have at least one first set of microdevice pad 110 facing the chiplet 112. The chiplet can have a second set of chiplet pad 116 on the opposite side from the first chiplet pad 114. The chiplet can be coupled to more than one microdevice 104, 106, and 108. There can be a separate bonding material holding the chiplet and microdevice together. The first set of microdevice pads 110 and the chiplet pads 114 can be bonded together and hold the microdevices and the chiplet together. There can be a pad 120 for microdevices that can connect to a system substrate.

Chiplet 112 can include a substrate. Either the first set of pad 114 or the second set of pad 116 is coupled to the pixel circuit through VIAs in the chiplet substrate.

During the transfer mechanism, the second set of pads can be bonded to a system substrate and coupled to electrodes on the system substrate. The electrodes can provide power, control signals, data or another form of electrical voltage or current. The cartridge layer 102 releases the bonded pixel element 150 to remain in the system substrate.

In one embodiment, the second set of chiplet pads can be formed to couple the second set of microdevices pads to an electrode or contact in the system substrate.

FIG. 2B shows a related embodiment where the first surface of the micro chiplet including the microdevices are covered by a passivation layer 130. In one related embodiment, the passivation layer 130 is bonded to the cartridge layers.

In one method of developing pixel elements related to FIG. 2B as compared to FIG. 1A, the micro chiplet is fabricated using circuit technologies such as CMOS or other technologies. The pads 114 are formed on the surface of the micro chiplet 112. The microdevices 104, 106, and 108 are bonded to the micro chiplet. Here, other processes may have been done such as forming interconnections, optical layers, color conversion layers or other device types. After such a process, the backside of the micro chiplet is thinned or the wafer is removed. Here, VIA is formed to connect micro chiplet interface signals to the other side of the micro chiplets. Pads 116 can form on the second side of the micro chiplet. The process of VIA formation and interconnection to the chiplet signals can be done prior to microdevice integration. The micro chiplet is bonded to a cartridge substrate or the cartridge structure is formed on the surface of the chiplet.

In another related method of developing pixel elements, the micro chiplet are integrated into a cartridge substrate. Then microdevices are bonded to the microdevices.

While the present disclosure is susceptible to various modifications and alternative forms, specific embodiments or implementations have been shown by way of example in the drawings and will be described in detail herein. However, it should be understood that the disclosure is not intended to be limited to the particular forms disclosed. Rather, the disclosure is to cover all modifications, equivalents, and alternatives falling within the spirit and scope of the invention as defined by the appended claims.

1. A cartridge structure the structure comprising:
a substrate, cartridge layers and a pixel element;
the pixel element comprising microdevices;
the microdevice having at least one first set of contact pad facing a chiplet;
the chiplet with pixel driving circuits having at least one first set of chiplet pad coupled to first set of contact pad of the microdevice; and
the chiplet having a second set of chiplet pad on an opposite side from the first chiplet pad.

2. The cartridge structure of claim 1, wherein the chiplet is coupled to more than one microdevice.

3. The cartridge structure of claim 2, wherein there is a separate bonding material holding the chiplet and microdevice together.

4. The cartridge structure of claim 3, wherein the first set of microdevice pads and the chiplet pads are bonded together.

5. The cartridge structure of claim 4, wherein the chiplet includes a substrate and either the first set of chiplet pad or the second set of pad is coupled to the pixel circuit through VIAs in the chiplet substrate.

6. The cartridge structure of claim 5, wherein the second set of pads are bonded to a system substrate and coupled to electrodes on the system substrate during a transfer.

7. A method to transfer a chiplet cartridge, the method comprising:
having the chiplet cartridge wherein the chiplet cartridge comprising:
a substrate, cartridge layers and a pixel element, with the pixel element comprising microdevices, the microdevice having at least one first set of contact pad facing a chiplet;
the chiplet with pixel driving circuits having at least one first set of chiplet pad coupled to first set of contact pad of the microdevice, the chiplet having a second set of chiplet pad on an opposite side from the first chiplet pad;
the method further comprising;
having the second set of pads bonded to a system substrate and coupled to electrodes on the system substrate; and
having the cartridge layer release a bonded pixel element to remain in the system substrate.

8. The method of claim 7, wherein the microdevices have pads on a side of microdevices that are different from the first set of microdevice pads.

9. The method of claim 8, wherein after transferring pixel elements to the system substrate, the electrodes are formed to couple the second set of microdevices pads to an electrode or contact in the system substrate.

10. (canceled)

11. (canceled)

12. (canceled)

13. (canceled)

14. (canceled)

15. A cartridge structure comprising:
a substrate, cartridge layers and a pixel element;
the pixel element comprising chiplets connected to the cartridge layers;
a chiplet having a first set of chiplet pads facing away from substrate and a second set of chiplet pads facing substrate;
microdevices coupled to the chiplet through at least one of the first set of chiplet pads; and
the microdevice having at least one first set of microdevice pads facing the chiplet.

16. The cartridge structure of claim 15, wherein the chiplet is coupled to more than one microdevice.

17. The cartridge structure of claim 16, wherein there is a separate bonding material holding the chiplet and microdevice together.

18. The cartridge structure of claim 17, wherein the first set of microdevice pads and the chiplet pads are bonded together.

19. The cartridge structure of claim 18, wherein the chiplet includes a substrate and either the first set of chiplet pad or the second set of pad is coupled to the pixel circuit through VIAs in the chiplet substrate.

20. The cartridge structure of claim 19, wherein the second set of pads are bonded to a system substrate and coupled to electrodes on the system substrate during a transfer.

21. (canceled)

22. (canceled)

23. (canceled)

24. (canceled)

25. (canceled)

26. (canceled)

27. (canceled)

28. (canceled)

29. (canceled)
